(19) United States
(12) Patent Application Publication
(10) Pub. No.: US 2025/0357149 A1
(43) Pub. Date: Nov. 20, 2025

(54) SUBSTRATE PROCESSING APPARATUS

(71) Applicant: Semes Co., Ltd, Cheonan-si (KR)

(72) Inventors: Seung Hoon OH, Cheonan-si (KR); Eun Seok KIM, Asan-si (KR); Hyung Gyu KIM, Ansan-si (KR)

(73) Assignee: Semes Co., Ltd, Cheonan-si (KR)

(21) Appl. No.: 19/207,553

(22) Filed: May 14, 2025

(30) Foreign Application Priority Data
May 14, 2024 (KR) 10-2024-0063122

(51) Int. Cl. H01L 21/67

(52) U.S. Cl. CPC H01L 21/67034

(57) ABSTRACT

Disclosed is a substrate treating apparatus of processing a substrate by using a supercritical fluid. The substrate treating apparatus includes: a housing for providing a treatment space for treating a substrate; a support unit for supporting a substrate in the treatment space; a fluid supply unit for supplying a fluid into the treatment space; a discharge unit for discharging the fluid in the treatment space; and an airflow guide unit provided in the treatment space, in which the airflow guide unit includes a guide plate positioned on an outer surface of the substrate in a state where the substrate is supported by the support unit. According to the exemplary embodiment, a pattern lining phenomenon may be prevented by preventing the generation of vortex in the process chamber.

### CROSS-REFERENCE TO RELATED APPLICATIONS

This application claims priority to and the benefit of Korean Patent Application No. 10-2024-0063122 filed in the Korean Intellectual Prope Office on May 14, 2024, the entire contents of which are incorporated herein by reference.

### TECHNICAL FIELD

The present invention relates to a substrate treating apparatus, and more particularly to an apparatus of processing a substrate by using a supercritical fluid.

### BACKGROUND ART

As the design rules of integrated circuit devices decrease, processes for forming deep and narrow patterns with high aspect ratios and accompanying cleaning and drying processes are required. In particular, methods have been proposed that utilize supercritical fluids to perform predetermined treatment processes, such as etching, cleaning and drying, on a substrate having a pattern with a high aspect ratio.

In one example, the cleaning process is carried out by cleaning an upper surface of the substrate with a volatile organic compound, and the drying process is carried out by supplying a fluid containing carbon dioxide (CO₂) in a supercritical state, or by supplying the fluid in a gaseous state and then changing the phase to a supercritical state to remove the volatile organic compound remaining on the substrate. At this time, the fluid is supplied from the lower part of the chamber toward the lower surface of the substrate because injecting the fluid containing CO₂ directly to the substrate during the drying process may damage the substrate. It also provides a blocking unit on the path of the supplied fluid so that the fluid is not injected directly to the substrate but is injected by detour. The fluid is induced by the blocking unit to the lower edge region of the substrate, and is supplied to the center region through the upper edge region of the substrate. In this case, a vortex may be formed while the fluid collides with the sidewall of the chamber. The formed vortex has a problem of damaging the pattern, such as causing a pattern lining phenomenon by pushing the liquid film formed on the upper surface of the substrate.

### SUMMARY OF THE INVENTION

The present invention has been made in an effort to provide a substrate treating apparatus capable of efficiently treating a substrate.

The present invention has also been made in an effort to provide a substrate treating apparatus capable of preventing pattern damage during a substrate drying treatment.

The present invention has also been made in an effort to provide a substrate treating apparatus capable of preventing vortex generation in a process chamber when a substrate is dried.

The objectives of the present disclosure are not limited thereto and other objectives not stated herein may be clearly understood by those skilled in the art from the following description.

An exemplary embodiment of the present invention, an apparatus of processing a substrate, the apparatus comprising: a housing for providing a treatment space for treating a substrate; a support unit for supporting a substrate in the treatment space; a fluid supply unit for supplying a fluid into the treatment space; a discharge unit for discharging the fluid in the treatment space; and an airflow guide unit provided in the treatment space, wherein the airflow guide unit may include a guide plate positioned on an outer surface of the substrate in a state where the substrate may be supported by the support unit.

According to the exemplary embodiment of the present invention, the fluid supply unit may include: a fluid supply source for storing the fluid; and a fluid supply line for connecting a lower supply port formed on a lower wall of the housing and the fluid supply source.

According to the exemplary embodiment of the present invention, wherein the housing may include: an upper body; a lower body positioned on a lower portion of the upper body; and a lifting member for opening and closing the treatment space by lifting any one of the upper body and the lower body.

According to the exemplary embodiment of the present invention, an upper surface of the guide plate may be provided to be flat.

According to the exemplary embodiment of the present invention, a groove may be formed in an edge region of an upper wall of the housing.

According to the exemplary embodiment of the present invention, the support unit includes: a support rod installed on the lower wall of the housing; a support plate installed on the support rod, spaced apart from the lower wall of the housing, and installed in a path of the fluid supplied to the lower supply port; and a plurality of support pins installed on the support plate and on which the substrate is placed, and the airflow guide unit further includes a plurality of fixing rods installed on an upper wall of the housing, and the guide plate may be installed on the fixed rod.

According to the exemplary embodiment of the present invention, the guide plate is provided in a ring shape, and an inner diameter of the guide plate may be provided larger than a diameter of the substrate supported by the support unit.

According to the exemplary embodiment of the present invention, the guide plate may be positioned at the same height as the substrate when the substrate supported on the support plate may be treated.

According to the exemplary embodiment of the present invention, the apparatus may further include a blocking plate spaced apart from the lower wall of the housing and installed in a path of the fluid injected from the lower supply port.

According to the exemplary embodiment of the present invention, the support unit includes: a support rod installed on an upper wall of the housing; a first support and a second support installed on the support rod; and a plurality of extension portions extending from the first support and the second support and having support protrusions for supporting the substrate, and the first support and the second support each has an arc shape and is positioned to face each other, and the airflow guide unit may include: a first guide plate having an arc shape; and a second guide plate positioned to face the first guide plate and having an arc shape.

According to the exemplary embodiment of the present invention, when the substrate supported by the first support and the second support is treated, the first guide plate and the second guide plate may be provided adjacent to the substrate.

According to the exemplary embodiment of the present invention, when the substrate supported by the first support and the second support is treated, the first guide plate and the second guide plate may be provided to surround a partial region of the substrate supported by the first support and the second support.

According to the exemplary embodiment of the present invention, when the substrate is treated, the first support, the second support, the first guide plate, and the second guide plate may be arranged to be combined to form a ring when viewed from above.

According to the exemplary embodiment of the present invention, when the substrate is treated, the first support, the second support, the first guide plate, and the second guide plate may be provided at the same height.

An exemplary embodiment of the present invention, an apparatus of processing a substrate, the apparatus comprising: an upper body; a lower body for providing a treatment space for treating a substrate in combination with the upper body; a lifting member for lifting any one of the upper body and the lower body; a support unit for supporting a substrate in the treatment space; a fluid supply unit for supplying a supercritical fluid to the treatment space; a discharge unit for discharging the supercritical fluid in the treatment space; a blocking plate installed while being spaced apart from a lower wall of the housing; and an airflow guide unit provided in the treatment space, the fluid supply unit includes: a fluid supply source for storing a raw material of the supercritical fluid; and a fluid supply line for connecting a lower supply port formed on the lower wall of the housing and the fluid supply source, the support unit includes: a first support for supporting a first side edge of the substrate; and a second support for supporting a second side edge of the substrate facing the first side edge, each of the first support and the second support includes: a support rod installed on an upper wall of the housing; a holder installed on the support rod and having an arc shape; and a support protrusion extending from the holder to an inside thereof, when viewed from above, the holder is positioned outside the substrate supported by the support unit, and the support protrusion is positioned to overlap an edge region of the substrate supported by the support unit, the airflow guide unit includes a first guide plate and a second guide plate provided to surround a partial region of the substrate in a state where the substrate is supported by the support unit, each of the first guide plate and the second guide plate has an arc shape, and when viewed from above, the substrate supported by the support unit may be surrounded by the first guide plate, the holder of the first support, the second guide plate, and the holder of the second support.

According to the exemplary embodiment of the present invention, the first guide plate, the holder of the first support, the second guide plate, and the holder of the second support may be combined with each other to form a ring in order.

According to the exemplary embodiment of the present invention, when the housing is closed, the first guide plate, the holder of the first support, the second guide plate, and the holder of the second support may be positioned at the same height.

An exemplary embodiment of the present invention, an apparatus of processing a substrate, the apparatus comprising: an upper body; a lower body for providing a treatment space for treating a substrate in combination with the upper body; a lifting member for lifting any one of the upper body and the lower body; a support unit for supporting a substrate in the treatment space; a fluid supply unit for supplying a fluid into the treatment space; a discharge unit for discharging a fluid in the treatment space; and an airflow guide unit provided in the treatment space, wherein the fluid supply unit includes: a fluid supply source for storing the fluid; and a fluid supply line for connecting a lower supply port formed on a lower wall of the housing and the fluid supply source, the support unit includes: a support rod installed in the lower body; a support plate installed on the support rod; and a plurality of support pins installed on the support plate and on which the substrate is placed, and the airflow guide unit includes: a plurality of fixing rods installed on the upper body; and a guide plate installed on the fixing rod and surrounding an exterior side of the substrate supported by the support unit in a state where the treatment space may be closed.

According to the exemplary embodiment of the present invention, when viewed from above, the guide plate may be provided in a ring shape.

According to the exemplary embodiment of the present invention, the guide plate may be adjacent to the substrate supported by the support unit and positioned at the same height as the substrate.

According to the exemplary embodiment of the present invention, pattern damage may be prevented during the substrate drying treatment.

According to the exemplary embodiment of the present invention, generation of a vortex in the process chamber can be prevented.

Effects of the present disclosure are not limited to those described above and effects not stated above will be clearly understood to those skilled in the art from the specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a diagram schematically illustrating an exemplary embodiment of a substrate treating apparatus of the present invention.

FIG. 2 is a diagram schematically illustrating an exemplary embodiment of the liquid treatment chamber of FIG. 1.

FIG. 3 is a diagram illustrating a phase change graph of carbon dioxide.

FIG. 4 is a diagram schematically illustrating an exemplary embodiment of a drying chamber of FIG. 1.

FIG. 5 is a diagram schematically illustrating a state in which a substrate is loaded into the drying chamber of FIG. 4.

FIG. 6 is a diagram schematically illustrating a state in which a substrate is loaded into and sealed in the drying chamber of FIG. 4.

FIG. 7 is a diagram schematically illustrating an airflow guide unit of FIG. 4.

FIG. 8 is a diagram illustrating the airflow guide unit and the substrate of FIG. 6 viewed from above.

FIG. 9 is a diagram schematically illustrating another exemplary embodiment of the drying chamber of FIG. 4.

FIG. 10 is a diagram schematically illustrating a state in which a substrate is loaded into the drying chamber of FIG. 9.

FIG. 11 is a diagram schematically illustrating a state in which a substrate is loaded into and sealed in the drying chamber of FIG. 10.

FIG. 12 is a diagram illustrating the airflow guide unit and the substrate of FIG. 11 viewed from above.

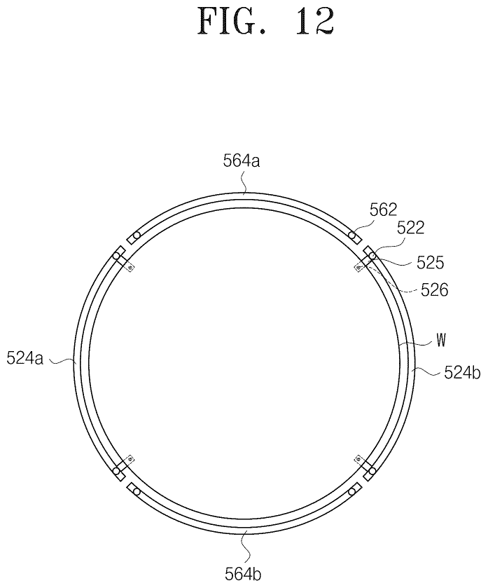

FIG. 13 is a diagram illustrating an appearance of a substrate when a substrate is treated in a general drying chamber.

FIG. 14 is a diagram schematically illustrating a state of treating a substrate in the drying chamber according to the exemplary embodiment of the present invention.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., +10%).

When the terms “about” or “substantially” are used in connection with a numerical value, it should be understood that the associated numerical value includes a manufacturing or operational tolerance (e.g., +10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer will be described as an example of an object to be treated. However, the technical spirit of the present invention may be applied to devices used for other types of substrate treatment, in addition to wafers.

Hereinafter, exemplary embodiments of the present invention will be described with reference to the accompanying drawings.

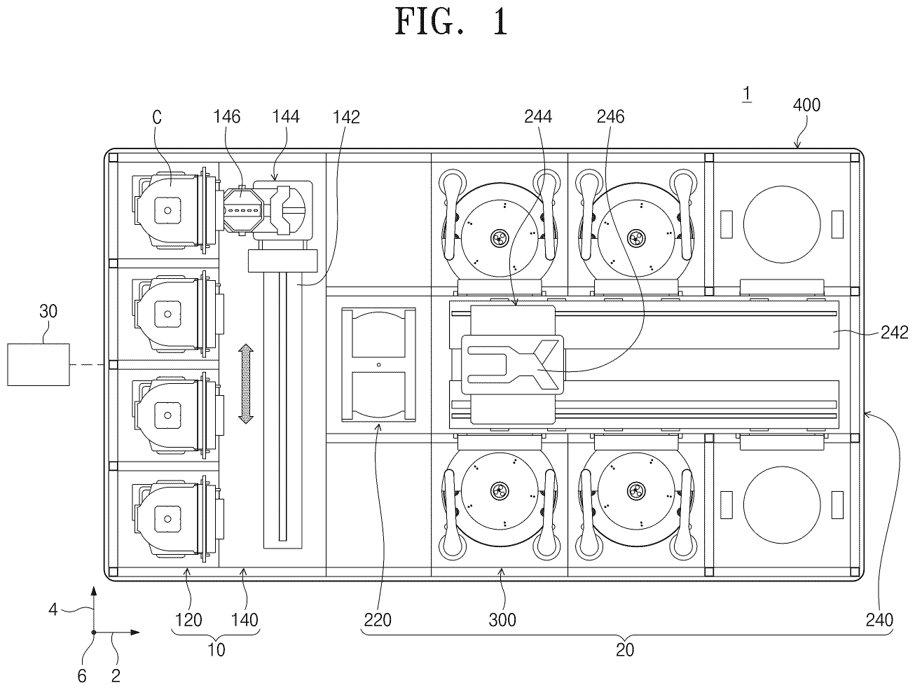

FIG. 1 is a diagram schematically illustrating an exemplary embodiment of a substrate treating apparatus of the present invention. Referring to FIG. 1, the substrate treating apparatus 1 includes an index module 10 and a treating module 20. According to the exemplary embodiment, the index module 10 and the treating module 20 are disposed in one direction. Hereinafter, a direction in which the index module 10 and the treating module 20 are arranged is defined as a first direction 2. When viewed from above, a direction perpendicular to the first direction 2 is defined as a second direction 4, and a direction perpendicular to a plane including both the first direction 2 and the second direction 4 is defined as a third direction 6.

The index module 10 transfers the substrate W from a cassette C in which the substrate W is accommodated to the treating module 20, which treats the substrate W. The index module 10 accommodates the substrate W that has been completely treated in the treating module 20 into the cassette C. A longitudinal direction of the index module 10 is provided in the second direction 4. The index module 10 includes a load port 110 and an index frame 140.

The cassette C, in which the substrate W is accommodated, is seated in the load port 120. The load port 120 is located at an opposite side of the treating module 20 based on the index module 140. A plurality of load ports 120 may be provided. A plurality of load ports 120 may be arranged in a line along the second direction 4. The number of load ports 120 may increase or decrease depending on process efficiency and footprint conditions of the treating module 20.

The cassette C is formed with a plurality of slots (not illustrated). The substrates W may be seated in the slots (not illustrated). The plurality of slots (not illustrated) may be spaced apart from each other in the third direction 6. The substrates W may be seated in the slots (not illustrated), respectively, and accommodated in the cassette C in a horizontally disposed state with respect to the ground.

As the cassette C, an airtight container, such as a Front Open Unified Pod (FOUP), may be used. The cassette C may be placed on the load port 120 by a transfer means (not illustrated), such as an overhead transfer, an overhead conveyor, or an automatic guided vehicle, or an operator.

An index rail 142 and an index robot 144 are provided inside the index frame 140. The index rail 142 is provided in the index frame 140 along the second direction 4 in its longitudinal direction. The index robot 144 may transfer the substrate W. The index robot 144 may transfer the substrate W between the index module 10 and the buffer unit 220, which will be described later.

The index robot 120 includes an index hand 146. On the index hand 146, the substrate W is seated. The index hand 146 may be provided on the index rail 142 to be movable along the second direction 4. Therefore, the index hand 146 is movable forward and backward along the index rail 142. Additionally, the index hand 146 may be provided to be rotatable about the third direction 6 as the axis. Additionally, the index hand 146 may be provided to be vertically movable along the third direction 6. A plurality of index hands 146 may be provided. The plurality of index hands 146 may be provided to be spaced apart from each other in the upward and downward direction. The plurality of index hands 146 may move forwardly, backwardly, and rotationally independently of each other.

The controller 30 may control the substrate treating apparatus 1. The controller 30 may include a process controller formed of a microprocessor (computer) that executes the control of the substrate treating apparatus 1, a user interface formed of a keyboard in which an operator performs a command input operation or the like in order to manage the substrate treating apparatus 1, a display for visualizing and displaying an operation situation of the substrate treating apparatus 1, and the like, and a storage unit storing a control program for executing the process executed in the substrate treating apparatus 1 under the control of the process controller or a program, that is, a treating recipe, for executing the process in each component according to various data and treating conditions. Further, the user interface and the storage unit may be connected to the process controller. The treatment recipe may be stored in a storage medium in the storage unit, and the storage medium may be a hard disk, and may also be a portable disk, such as a CD-ROM or a DVD, or a semiconductor memory, such as a flash memory.

The controller 30 may control the substrate treating apparatus 1 so as to perform a substrate treating method described below. For example, the controller 30 may control the configurations provided in the drying chamber 400 to perform a substrate treating method described below.

The treating module 20 includes a buffer unit 220, a transfer frame 240, a liquid treating chamber 300, and a drying chamber 400. The buffer unit 220 provides a buffer space where the substrate W loaded into the treating module 20 and the substrate W being unloaded from the treating module 20 temporarily stay. The transfer frame 240 provides a transfer space for transferring the substrate W between the buffer unit 220, the liquid treating chamber 300, and the drying chamber 400.

The liquid treating chamber 300 may perform a liquid treatment process by supplying liquid onto the substrate W to liquid-treat the substrate W. The drying chamber 400 may perform a drying process to remove any remaining liquid on the substrate W. The liquid treating chamber 300 and the drying chamber 400 may perform a cleaning process. The cleaning process may be performed sequentially in the liquid treating chamber 300 and the drying chamber 400. For example, the liquid treating chamber 300 may treat the substrate W by supplying chemicals, rinse solutions, and/or organic solvents onto the substrate W. For example, in the drying chamber 400, a drying treatment may be performed by using a supercritical fluid to remove any residual liquid on the substrate W.

The buffer unit 220 may be disposed between the index frame 140 and the transfer frame 240. The buffer unit 220 may be located at one end of the transfer frame 240. A slot (not illustrated) in which the substrate W is placed is provided inside the buffer unit 220. A plurality of slots (not illustrated) is provided. The plurality of slots (not illustrated) may be spaced apart from each other along the third direction 6. A front face and a rear face of the buffer unit 220 are opened. The front face may be the side facing the index frame 140, and the rear face may be the side facing the transfer frame 240. The index robot 144 may approach the buffer unit 220 through the front face, and a transfer robot 244 to be described later may approach the buffer unit 220 through the rear face.

A longitudinal direction of the transfer frame 240 may be provided along the first direction 2. The liquid treating chamber 300 and the drying chamber 400 may be disposed on both sides of the transfer frame 240. The liquid treating chamber 300 and the drying chamber 400 may be disposed on the lateral portion of the transfer frame 240. The transfer frame 240 and the liquid treating chamber 300 may be disposed along the second direction 4. Also, the transfer frame 240 and the drying chamber 400 may be disposed along the second direction 4.

In one example, the liquid treating chambers 300 are disposed on opposite sides of the transfer frame 240, and the drying chambers 400 are disposed on opposite sides of the transfer frame 240. The liquid treating chambers 300 may be disposed relatively closer to the buffer unit 220 than the drying chambers 400. At one side of the transfer chamber 240, the liquid treating chambers 300 may be provided in an arrangement of A×B (each of A and B is 1 or a natural larger than 1) in the first direction 2 and the third direction 6. Here, A is the number of liquid treating chambers 300 provided in a line along the first direction 2, and B is the number of liquid treating chambers 300 provided in a line along the third direction 6. For example, when four liquid treating chambers 300 are provided on one side of the transfer frame 240, the liquid treating chambers 300 may be arranged in a 2×2 arrangement. The number of liquid treating chambers 300 may be increased or decreased. As described above, the liquid treating chambers 300 may be provided only on one side of the transfer frame 240, and only the drying chambers 400 may be arranged on the other side opposite the one side. Further, the liquid treating chamber 300 and the drying chamber 400 may be provided in a single layer on one side and opposite sides of the transfer frame 240.

The transfer frame 240 includes a guide rail 242 and a transfer robot 244. The guide rail 242 and the transfer robot 244 are provided inside the transfer frame 240. A longitudinal direction of the guide rail 242 may be provided in the first direction 2. The transfer robot 244 may be provided on the guide rail 242 to be linearly movable along the first direction 2. The transfer robot 244 transfers the substrate W between the buffer unit 220, the liquid treating chamber 300, and the drying chamber 400.

The transfer robot 244 includes a transfer hand 246 on which the substrate W is placed. The transfer hand 246 may be provided on the guide rail 242 to be movable along the first direction 2. Accordingly, the transfer hand 246 is movable forwardly and backwardly along the guide rail 242. In addition, the transfer hand 246 may be provided to be rotatable about the third direction 6 and to be movable along the third direction 6. A plurality of transfer hands 246 may be provided. The plurality of transfer hands 246 may be provided to be spaced apart from each other in the vertical direction. The plurality of transfer hands 246 may move forwardly, backwardly, and rotationally independently of each other.

The liquid treating chamber 300 performs a liquid-treatment process on the substrate W. For example, the liquid treating chamber 300 may be a chamber that performs a cleaning process to remove impurities, such as process byproducts or particles, adhering to the substrate W. The liquid treating chamber 260 may have a different structure depending on the type of process treating the substrate W. Unlike this, each of the liquid treating chambers 300 may have the same structure.

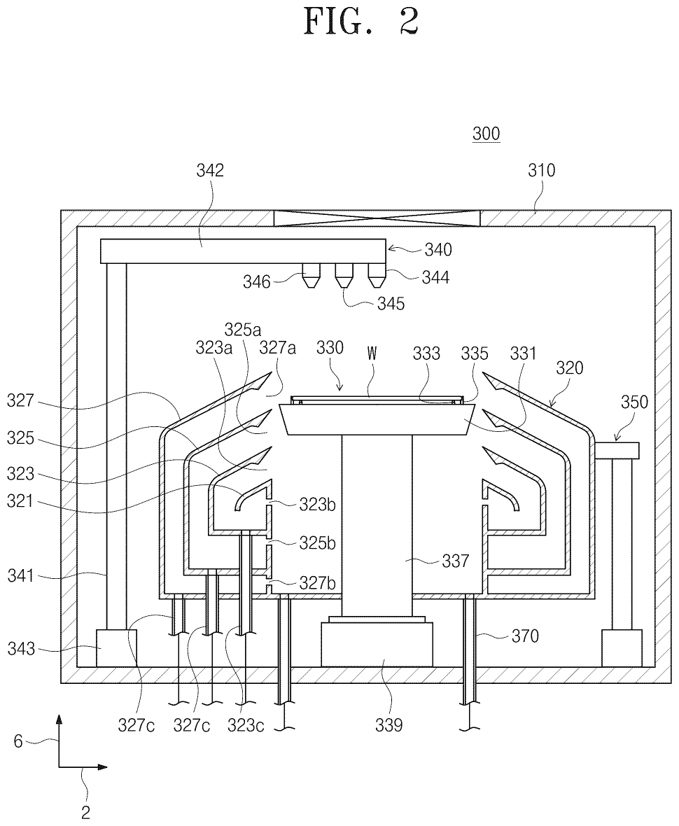

FIG. 2 is a diagram schematically illustrating an exemplary embodiment of the liquid treatment chamber of FIG. 1. Referring to FIG. 2, the liquid treating chamber 300 includes a chamber 310, a treatment container 320, a support member 330, and a liquid supply unit 340.

The chamber 310 has an interior space. The chamber 310 is provided in a generally cuboidal shape. An opening (not illustrated) is formed in one side of the chamber 310. The opening (not illustrated) functions as an entrance port through which the substrate W is loaded into and unloaded from of the interior space of the chamber 310 by the transfer robot 244. The treatment container 320, the support member 330, and the liquid supply unit 340 are disposed in the interior space of the chamber 310.

The treatment container 320 has a treatment space with an opened upper portion. The treatment container 320 may be a bowl having a treatment space. The treatment container 320 may be provided to surround the treatment space. The treatment space of the treatment container 320 is provided as a space for the substrate W to be supported and rotated by the support member 330 described later. Furthermore, the treatment space is provided as a space for the liquid supply unit 340, described later, to supply a liquid onto the substrate W to treat the substrate W.

According to the example, the treatment container 320 may have a guide wall 321 and a plurality of recovery containers 323, 325, and 327. Each of the recovery containers 323, 325, and 327 separately collects different liquids from the liquids used to treat the substrate W. The recovery containers 323, 325, and 327 may each have a recovery space for recovering the liquid used to treat the substrate W.

The guide wall 321 and the recovery containers 323, 325, and 327 are provided in the form of an annular ring surrounding the support member 330. When a liquid is supplied onto the substrate W, the liquid that is scattered by the rotation of the substrate W may enter the recovery space through the inlets 323a, 325a, and 327a of the recovery containers 323, 325, and 327 described below. Different types of liquid may be introduced into of the recovery containers 323, 325, and 327, respectively.

The treatment container 320 includes a guide wall 321, a first recovery container 323, a second recovery container 325, and a third recovery container 327. The guide wall 321 is provided in the shape of an annular ring that surrounds the support member 330. The first recovery container 323 is provided in an annular ring shape surrounding the guide wall 321. The second recovery container 325 is provided in an annular ring shape surrounding the first recovery container 323. The third recovery container 327 is provided in an annular ring shape surrounding the second recovery container 325.

The space between the guide wall 321 and the first recovery container 323 functions as a first inlet 323a through which the liquid is introduced. A space between the first recovery container 323 and the second recovery container 325 functions as a second inlet 325a through which the liquid is introduced. A space between the second recovery container 325 and the third recovery container 327 functions as a third inlet 327a through which the liquid is introduced. The second inlet 325a may be located above the first inlet 323a, and the third inlet 327a may be located above the second inlet 325a. The liquid introduced into the first inlet 323a, the liquid introduced into the second inlet 325a, and the liquid introduced into the third inlet 327a may be different types of liquid.

The space between the bottom of the guide wall 321 and the first recovery container 323 functions as a first outlet 323b, through which impurities and airflow generated from the liquid are discharged. The space between the bottom of the first recovery container 323 and the second recovery container 325 functions as a second outlet 325b, through which impurities and airflow generated from the liquid are discharged. The space between the bottom of the second recovery container 325 and the third recovery container 327 functions as a third outlet 327b, through which impurities and airflow generated from the liquid are discharged. The impurities and airflow discharged from the first outlet 323b, the second outlet 325b, and the third outlet 327b are exhausted to the outside of the liquid treating chamber 300 via the exhaust unit 370 described later.

Recovery lines 323c, 325c, and 327c extending vertically downwardly are connected to the bottom surface of the recovery containers 323, 325, and 327, respectively. The recovery lines 323c, 325c, and 327c discharge the liquids that have been introduced through the recovery containers 323, 325, and 327, respectively. The discharged treatment liquid may be reused via an external liquid reclamation system (not illustrated).

The support member 330 supports and rotates the substrate W within the treatment space. The support member 330 may have a spin chuck 331, a support pin 333, a chuck pin 335, a rotation shaft 337, and a driver 339.

The spin chuck 331 has a top surface that is substantially circular when viewed from above. The top surface of the spin chuck 331 may have a diameter larger than the substrate W.

A plurality of support pins 333 is provided. The support pin 333 is disposed on the top surface of the spin chuck 331. The support pins 333 are spaced apart at regular intervals at the edge portion of the top surface of the spin chuck 331. The support pins 333 are formed to protrude upwardly from above surface of the spin chuck 331. The support pins 333 are arranged in combination with each other to form an overall annular ring shape. The support pin 333 supports an edge region of the rear surface of the substrate W so that the substrate W is spaced apart from above surface of the spin chuck 331 at a predetermined distance.

A plurality of chuck pins 335 is provided. The chuck pins 335 are disposed relatively farther away from the center region of the spin chuck 331 than the support pins 333. The chuck pins 335 protrude upwardly from above surface of the spin chuck 331. The chuck pin 335 supports a lateral region of the substrate W to prevent the substrate W from laterally deviating from its stationary position when the substrate W is rotated.

The rotation shaft 337 is coupled with the spin chuck 331. The rotation shaft 337 is coupled to the bottom surface of the spin chuck 331. The rotation shaft 337 may be provided with a longitudinal direction facing the third direction 6. The rotation shaft 337 is provided to be rotatable by receiving power from the driver 339. The rotation shaft 337 is rotated by the driver 339, and the spin chuck 331 is rotated by a medium of the rotation shaft 337. The driver 339 rotates the rotation shaft 337. The driver 339 is capable of varying the rotational speed of the rotation shaft 337. The driver 339 may be a motor that provides driving force. However, the driver is not limited thereto, and may be provided in various variations with any known device that provides driving force.

The liquid supply unit 340 supplies the liquid to the substrate W. The liquid supply unit 340 supplies a liquid to the substrate W supported on the support member 330. The liquid supplied to the substrate W by the liquid supply unit 340 may be provided in a plurality of types. The liquid supply unit 340 may include a support rod 341, an arm 342, a driver 343, a first liquid supply nozzle 344, and a second liquid supply nozzle 345.

A support rod 341 is positioned in the interior space of the chamber 310. The support rod 341 may be positioned on one side of the treatment container 320 in the interior space. The support rod 2641 may have a rod shape in which a longitudinal direction faces the third direction 6. The support rod 341 is provided to be rotatable by the driver 343 to be described later.

The arm 342 is coupled to an upper end of the support rod 341. The arm 342 extends vertically from the longitudinal direction of the support rod 341. The arm 342 may be provided in the third direction 6 along its length. The first liquid supply nozzle 344, the second liquid supply nozzle 345, and the third liquid supply nozzle 346 to be described later may be fixedly coupled to the end of the arm 342.

The arm 342 may be provided to be movable forwardly and backwardly along its longitudinal direction. The arm 342 may be swing moveable via the support rod 341 by the driver 343 that rotates the support rod 341. By the rotation of the arm 342, the first liquid supply nozzle 344, the second liquid supply nozzle 345, and the third liquid supply nozzle 346 may also be swing-moved to be moved between a process position and a standby position.

The process position may be a position where any one of the first liquid supply nozzle 344, the second liquid supply nozzle 345, and the third liquid supply nozzle 346 faces the substrate W supported by the support member 330. According to the example, the process position may be a position where a center of any one of the first liquid supply nozzle 344, the second liquid supply nozzle 345, and the center of the substrate W supported by the support member 330 faces each other. The standby position may be a position where the first liquid supply nozzle 344, the second liquid supply nozzle 345, and the third liquid supply nozzle 346 are all out of the process position.

The driver 343 is coupled with the support rod 341. The driver 343 may be disposed on the bottom surface of the chamber 310. The driver 343 provides driving force for rotating the support rod 341. The driver 343 may be provided as a known motor that provides driving force.

The first liquid supply nozzle 344 supplies the first liquid onto the substrate W. The first liquid supply nozzle 344 may supply the first liquid onto the substrate W supported by the support member 330. The second liquid supply nozzle 345 supplies the second liquid onto the substrate W. The second liquid supply nozzle 345 supplies the second liquid onto the substrate W supported by the support member 330. The third liquid supply nozzle 346 supplies a third liquid onto the substrate W. The third liquid supply nozzle 346 supplies the third liquid onto the substrate W supported on the support member 330.

According to the exemplary embodiment, the first solution, the second solution, and the third solution may be any one of chemical, rinse solution, and organic solvent. For example, the chemical may include diluted sulfuric acid (H₂SO₄), phosphoric acid (P₂O₅), hydrofluoric acid (HF), and ammonium hydroxide (NH₄OH). For example, the rinse liquid may include water or deionized water (DIW). For example, the organic solvent may include alcohol, such as isopropyl alcohol (IPA). According to the exemplary embodiment, the first liquid may be chemical. Also, the second liquid may be a rinse liquid. Further, the third liquid may be an organic solvent.

The exemplary embodiment of the present invention has been described based on the case where in the liquid supply unit 340, the first liquid supply nozzle 344, the second liquid supply nozzle 345, and the third liquid supply nozzle 346 are all coupled to the arm 342 as an example, but the present invention is not limited thereto. For example, the first liquid supply nozzle 344, the second liquid supply nozzle 345, and the third liquid supply nozzle 346 may each independently have an arm, a support rod, and a driver, and may independently move between a process position and a standby position by swing movement and forward/rearward movement.

The lifting unit 350 is disposed in the interior space of the chamber 310. The lifting unit 350 adjusts the relative height between the treatment container 320 and the support member 330. The lifting unit 350 may move the treatment container 320 in a straight line in the third direction 6. Accordingly, since the height of the recovery containers 323, 325, and 327 for recovering the liquid is changed according to the type of the liquid supplied to the substrate W, the liquids may be separated and collected. As described above, the treatment container 320 is fixedly installed, and the lifting unit 350 may move the support member 330 in an upward or downward direction to change the relative height between the support member 330 and the treatment container 320.

The exhaust unit 370 exhausts impurities generated in the treatment space. Impurities generated during liquid treatment of the substrate W are exhausted by a pressure reducing unit (not illustrated) provided in the exhaust unit 370. The exhaust unit 370 may be coupled to the bottom surface of the treatment container 320. In one example, the exhaust unit 370 may be disposed in the space between the rotation shaft 337 and the inner wall of the treatment container 320.

The drying chamber 400 may be a process chamber that is sealed from the outside environment. The drying chamber 400 utilizes a process fluid to remove any residual liquid on the substrate W. In one example, the drying chamber 400 uses a supercritical fluid to remove the third liquid (e.g., an organic solvent) that remains on the substrate W. In the drying chamber 400, a supercritical process is performed by using the properties of the supercritical fluid. Representative examples thereof include a supercritical drying process and a supercritical etching process. Hereinafter, the supercritical process will be described based on the supercritical drying process. However, this is for ease of understanding only, and the drying chamber 400 may perform other supercritical processes other than the supercritical drying process. In the exemplary embodiment, the supercritical fluid may be supercritical carbon dioxide (scCO₂).

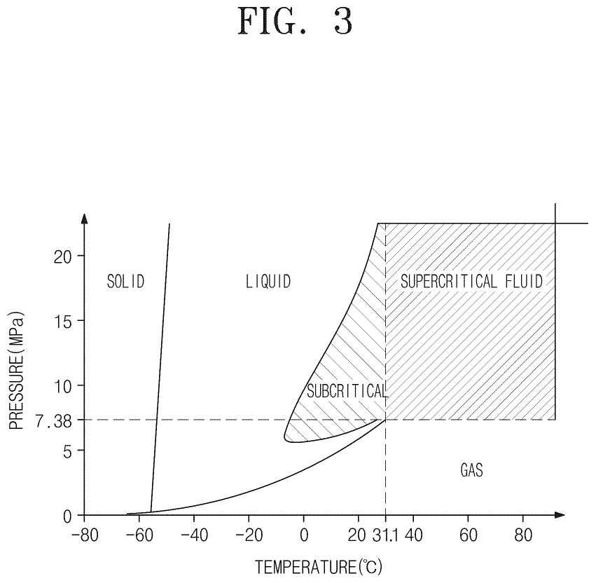

FIG. 3 is a diagram illustrating a phase change graph of carbon dioxide. Referring to FIG. 3, carbon dioxide has a critical temperature of 31.1° C. and a relatively low critical pressure of 7.38 MPa, so that carbon dioxide may be easily made to a supercritical state, and it is easy to control phase change of carbon dioxide by adjusting temperature and pressure, and carbon dioxide is low priced. In addition, carbon dioxide is non-toxic and harmless to the human body, and has characteristics of non-combustibility and inertness. Compared with water or other organic solvents, the diffusion coefficient of supercritical carbon dioxide is about 10 to 100 times higher, so that penetration of the supercritical carbon dioxide is fast, and the supercritical carbon dioxide is quickly replaced with the organic solvents. In addition, since supercritical carbon dioxide has almost no surface tension, the supercritical carbon dioxide has advantageous properties to be used for drying the substrate W including a fine circuit pattern. In addition, by-product of various chemical reactions of the supercritical carbon dioxide may be recycled, and at the same time, the supercritical carbon dioxide may be converted into a gas after being used in the supercritical drying process and the organic solvent may be separated and reused, so that there is less burdensome in terms of environmental pollution.

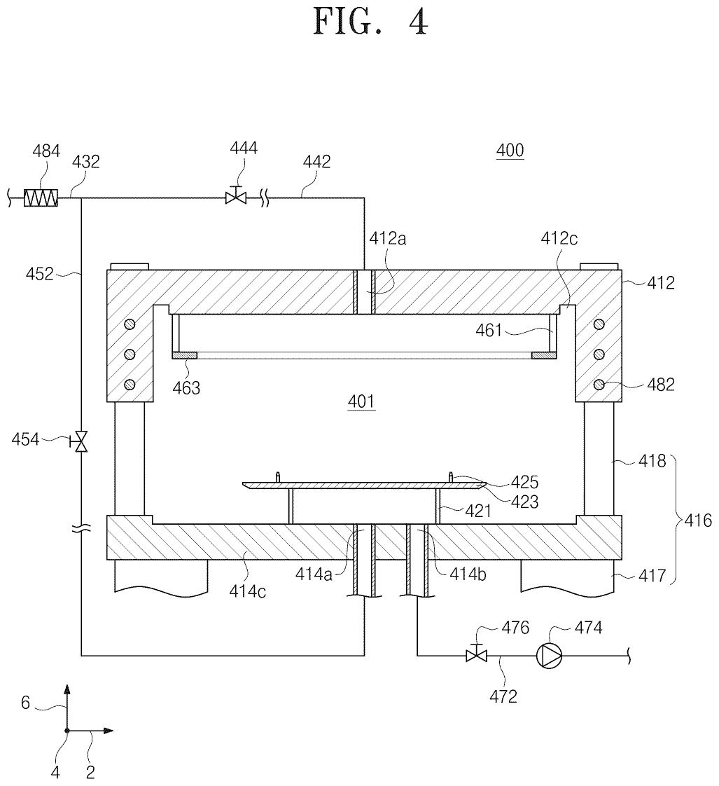

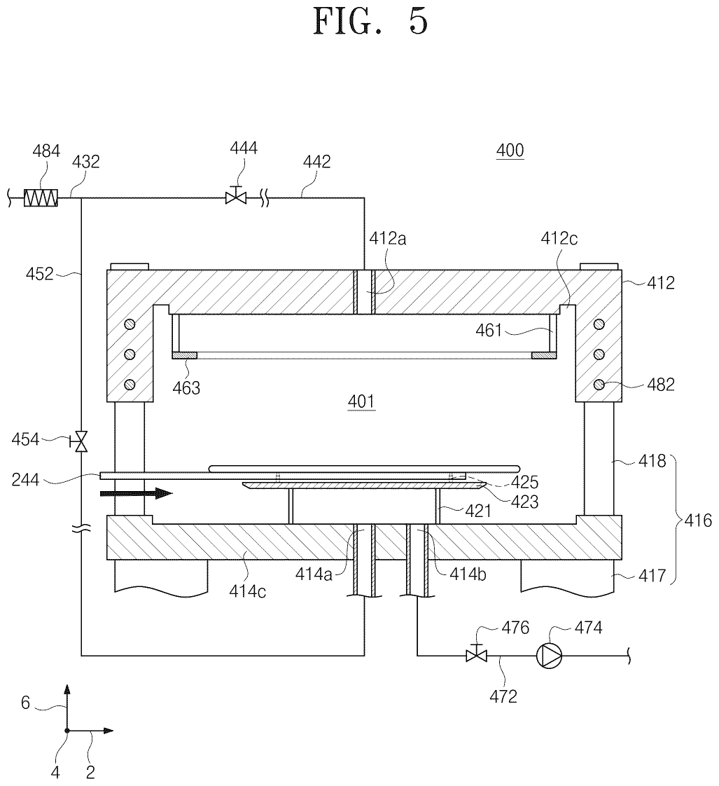

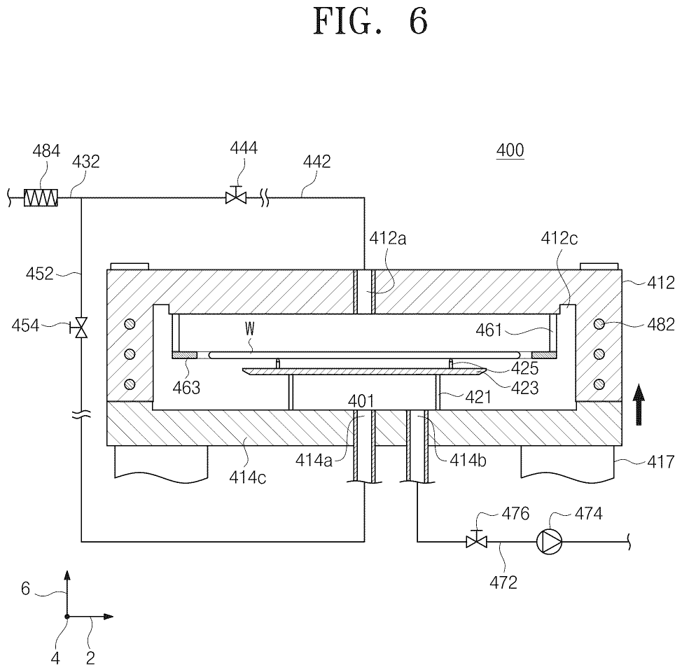

FIG. 4 is a diagram schematically illustrating an exemplary embodiment of the drying chamber of FIG. 1, and FIGS. 5 and 6 are diagrams illustrating a state in which a substrate is loaded into the drying chamber of FIG. 4 and the treatment space is sealed. Referring to FIGS. 4 to 6, the drying chamber 400 may include a housing 410, a support unit 420, a fluid supply unit 430, an airflow guide unit 460, a fluid discharge unit 470, a heating unit 480, and a blocking unit 490.

The housing 410 has a treatment space 401 therein. A drying process for the substrate W may be performed in the treatment space 401. According to the exemplary embodiment, the substrate W treated in the treatment space 401 may be the substrate W on which a pattern is formed on the upper surface thereof through an exposure process and a development process, and a liquid film L is formed on the upper surface thereof. Also, the drying process may be a process of drying the liquid layer L formed on the upper surface of the substrate W. According to the exemplary embodiment, the liquid film L may be an organic solvent. Also, the organic solvent may include isopropyl alcohol (IPA).

An opening (not illustrated) through which the substrate W is loaded and unloaded may be formed at one side of the housing 410. A door (not illustrated) for opening and closing the opening may be provided in the opening. The door (not illustrated) may be movable in an upward and downward direction to open and close the opening (not illustrated), and to keep the housing 410 in a sealed state. Also, unlike the above example, the housing 410 may include an upper body 412, a lower body 414, and a lifting member 416. The housing 410 may be opened and closed by lifting the upper body 412 or the lower body 414 by the lifting member 416. Hereinafter, the present invention has been described based on the case where the housing 410 includes the upper body 412, the lower body 414, and the lifting member 416 as an example.

The upper body 412 and the lower body 414 are disposed along the third direction 6. The upper body 412 is positioned above the lower body 414. The upper body 412 includes an upper wall 412b. The upper wall 412b includes a stepped groove 412c. The groove 412c may be formed in an edge region of the upper wall 412b. The groove 412c is formed to be in contact with the treatment space 401.

Supply ports 412a and 414a may be formed in the upper body 412 and the lower body 414, respectively. The fluid supply unit 430 to be described later may be connected to each supply port 412a. Accordingly, the fluid may be supplied to the treatment space 401. According to the exemplary embodiment, the upper supply port 412a formed in the upper body 412 may be formed in the center region of the upper body 412 when viewed from above. Furthermore, the lower supply port 414a formed in the lower body 414 may be formed in the center region of the lower body 414 when viewed from above. Further, a discharge port 414b may be formed on the lower body 414. The discharge port 414b may be formed at a location that is eccentrically located a certain distance from the center axis of the second body 414 when viewed from above. For example, the discharge port 414b may be formed at a position spaced a certain distance from the position where the supply port 414a is formed.

The upper body 412 and the lower body 414 are combined with each other to define the treatment space 401. The treatment space 401 may be sealed such that the upper body 412 and the lower body 414 are in close contact with each other. The substrate W is treated in the sealed treatment space 401.

The lifting member 416 lifts the lower body 414. The lifting member 416 may include a lifting cylinder 419 and a lifting rod 418. The lifting cylinder 417 may be coupled to the lower body 414. According to the exemplary embodiment, since the lifting cylinder 417 is coupled to the lower body 414, the lower body 414 may be lifted and move. Alternatively, a position of the upper body 412 may be fixed.

The lifting cylinder 417 may move the lower body 414 to separate the upper body 412 and the lower body 414 from each other. When the upper body 412 and the lower body 414 are separated from each other, the treatment space 401 is opened. When the treatment space 401 is opened, the substrate W may be loaded into the treatment space 401, or the substrate W may be unloaded from the treatment space 401. The substrate W loaded into the treatment space 401 may be the substrate W that has been completely liquid treated in the liquid treating chamber 300. For example, the substrate W loaded into the treatment space 401 may be a substrate W having organic solvent residue on its top surface. FIG. 5 illustrates that the transfer robot 244 enters the treatment space 401 in the first direction 2 for better understanding. However, the present invention is not limited thereto, and the transfer robot 244 may also enter the treatment space 401 in the second direction 4. The transfer robot 244 then transfers the substrate W to the support unit 420.

The lifting cylinder 417 may move the lower body 414 to closely contact the upper body 412 and the lower body 414. The lifting cylinder 417 may overcome a pressure greater than or equal to a critical pressure of the treatment space 401 while the drying process for the substrate W is performed, and closely contact the upper body 412 and the lower body 414 to seal the treatment space 401 from an external environment.

The lifting rod 418 generates lifting force. For example, the lifting rod 418 may generate force that moves in the third direction 6. The lifting rod 418 may be formed with its longitudinal direction facing the third direction 6. One end of the lifting rod 418 may be inserted into the lifting cylinder 419. The other end of the lifting rod 418 may be coupled to the upper body 412. The lower body 414 may move in the third direction 6 by the relative lifting motion of the lifting cylinder 417 and the lifting rod 418. While the lower body 414 moves in the vertical direction (e.g., the third direction 6), the lifting rod 418 prevents the upper body 412 and the lower body 414 from moving in the horizontal direction (e.g., the first direction 2 and the second direction 4). The lifting rod 418 guides the vertical movement direction of the lower body 414. The lifting rod 418 may prevent the upper body 412 and the lower body 414 from being separated from each other at regular positions.

According to one example of the present invention described above, the present invention has been described based on the case where the lower body 424 moves in the upward and downward direction to seal the treatment space 414 as an example, but is not limited thereto. For example, the upper body 412 and the lower body 414 may be moved in the vertical direction, respectively. In addition, the upper body 412 may move in the vertical direction, and the lower body 414 may be fixed in position.

The support unit 420 supports the substrate W within the treatment space 401. The support unit 420 may include a support rod 421, a support plate 423, and a support pin 425.

According to the example, the support rod 421 may be provided in a rod shape. The support rod 421 is formed to protrude upwardly from the lower wall 414c of the lower body 414. The support rod 421 may have a shape extending from the lower wall 414c of the lower body 414 toward the third direction 6. A plurality of support rods 421 may be provided. A plurality of support rods 421 may be provided in the same length. The plurality of support rods 421 are disposed to be spaced apart from each other by a predetermined distance. The support plate 423 is coupled to an upper portion of the support rod 421.

The support plate 423 may be provided to be spaced apart from the lower wall 414c of the lower body 414 by a predetermined distance. The support plate 423 may be fixed to the lower body 414 by the support rod 421. The diameter of the support plate 423 may be provided smaller than the diameter of the substrate W. The support plate 423 may be provided on the path of the fluid supplied from the lower supply port 414b. When viewed from above, the support plate 423 may be installed at a position overlapping the lower supply port 414a and the discharge port 414b formed in the lower body 414. Accordingly, the fluid supplied to the lower supply port 414b may be prevented from being directly injected onto the lower surface of the substrate W, thereby preventing damage to the substrate.

The support pin 425 supports the lower surface of the substrate W. The support pin 425 may be installed such that the substrate W is spaced apart from the support plate 423 by a predetermined distance. The support pin 425 may be provided on an upper surface of the support plate 423. The support pin 425 may be fixedly installed on the support plate 423. Also, the support pin 425 may be provided in a protrusion shape. The support pins 425 may be provided in plurality.

In the above-described example, the support unit 420 may include a plurality of lift pins (not illustrated) installed to be ascending and descending on the support plate 423. The lift pins may extend upwardly on the support plate 423 and may contact and support a center region of the substrate W. As the lift pins ascend and descend, heights of uppermost ends of the lift pins may be changed. Accordingly, the support unit 420 may support the substrate W at an adjustable height.

The fluid supply unit 430 supplies the fluid to the treatment space 401. In the exemplary embodiment, the fluid may be supercritical carbon dioxide (scCO₂). Hereinafter, for convenience of description, the present invention will be described based on the case where the fluid supply unit 430 supplies a supercritical fluid including supercritical carbon dioxide (scCO₂) to the treatment space 401 as an example.

The fluid supply unit 430 may include a main supply pipe 432, a first fluid supply unit 440, and a second fluid supply unit 450.

The main supply pipe 432 may supply a fluid to the first fluid supply unit 440 and the second fluid supply unit 450. One end of the main supply pipe 432 is connected to a storage source 433 in which the supercritical fluid is stored. According to the exemplary embodiment, the storage source 433 may be a reservoir. The other end of the main supply pipe 432 may be branched into a first supply pipe 442 and a second supply pipe 452 to be described later. A second heater 484 to be described later may be installed in the main supply pipe 432.

The first fluid supply unit 440 supplies the supercritical fluid to the treatment space 401. The first fluid supply unit 440 supplies the supercritical fluid to the treatment space 401 via the upper supply port 412a formed in the upper body 412. According to an exemplary embodiment, the first fluid supply unit 440 may supply the supercritical fluid to the upper region of the treatment space 401. The first fluid supply unit 440 may supply the supercritical fluid in a direction toward the upper surface of the substrate W supported by the support unit 420.

The first fluid supply unit 440 may include a first supply pipe 442 and a first valve 444. One end of the first supply pipe 442 is branched from the main supply pipe 432. The other end of the first supply pipe 442 is connected to the upper supply port 412a. The first supply pipe 442 receives a supercritical fluid from the main supply pipe 432 and supplies the supercritical fluid to the treatment space 401 through the upper supply port 412a.

The first valve 444 is installed at the first supply pipe 442. The first valve 444 may be provided as an opening/closing valve capable of selectively opening and closing the first supply pipe 442. When the first valve 444 is opened, the supercritical fluid stored in the storage source (not illustrated) may be supplied to the treatment space 401 via the main supply pipe 432, the first supply pipe 442, and the upper supply port 412a.

Although the present invention has been described based on the case where the first valve 444 is an opening/closing valve as an example, the present invention is not limited thereto, and the first valve 444 may be a flow rate control valve. As the flow rate control valve 444 adjusts the flow rate inside the first supply pipe 442, the flow rate per unit time of the supercritical fluid supplied to the treatment space 401 may be changed. The flow rate per unit time of the supercritical fluid supplied to the treatment space 401 may be changed so that the pressure by the supercritical fluid inside the first supply pipe 442 and the treatment space 401 may be changed.

The second fluid supply unit 450 supplies a supercritical fluid to the treatment space 401. The second fluid supply unit 450 supplies a supercritical fluid to the treatment space 401 via the lower supply port 414a formed in the lower body 414. According to the exemplary embodiment, the second fluid supply unit 450 may supply a supercritical fluid to a lower region of the treatment space 401. The second fluid supply unit 450 may supply a supercritical fluid in a direction toward a lower surface of the substrate W supported by the support unit 420.

The second fluid supply unit 450 may include a second supply pipe 452 and a second valve 454. One end of the second supply pipe 452 is branched from the main supply pipe 432. The other end of the second supply pipe 452 is connected to the lower supply port 414a. The second supply pipe 452 receives a supercritical fluid from the main supply pipe 432 and supplies the supercritical fluid to the treatment space 401 through the lower supply port 414a.

The second valve 454 is installed in the second supply pipe 452. The second valve 454 may be provided as an opening/closing valve that selectively opens and closes the second supply pipe 452. When the second valve 454 is opened, the supercritical fluid stored in the storage source (not illustrated) may be supplied to the treatment space 401 through the main supply pipe 432, the second supply pipe 452, and the lower supply port 414a.

Although the present invention has been described based on the case where the second valve 454 is an opening/closing valve as an example, the present invention is not limited thereto, and the second valve 454 may be a flow rate control valve. As the flow rate control valve 454 adjusts the open flow rate, the flow rate per unit time of the supercritical fluid supplied to the treatment space 401 may be changed. The flow rate per unit time of the supercritical fluid supplied to the treatment space 401 may be changed so that the pressure by the supercritical fluid inside the second supply pipe 452 and the treatment space 401 may be changed.

The above-described flow rate control valve may be provided as a metering valve. Optionally, the flow rate control valve may be provided as a pendulum valve or a buffer fly valve. However, the type of the flow rate control valve is not limited thereto, and may be variously modified and provided as a known flow rate control valve capable of controlling a flow rate of a fluid.

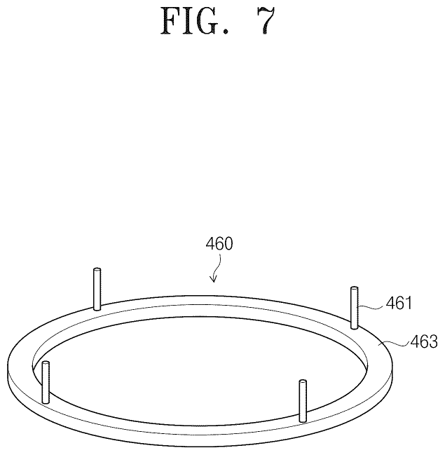

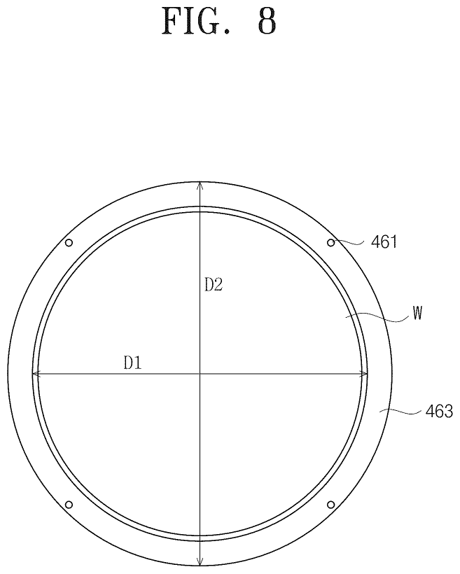

FIG. 7 is a diagram schematically illustrating the airflow guide unit of FIG. 4, and FIG. 8 is a diagram illustrating the airflow guide unit and the substrate of FIG. 6 viewed from above. Referring to FIGS. 7 and 8, the airflow guide unit 460 includes a fixing rod 461 and a guide plate 463. The fixing rod 461 is provided with a longitudinal direction facing up and down. A plurality of fixing rods 422 may be provided. A plurality of fixing rods 461 may be provided with the same length. The plurality of fixing rods 461 is spaced apart from each other. The guide plate 463 is coupled to each of the fixing rods 461.

The guide plate 463 may be installed in the upper body 412. The guide plate 463 may be coupled to a lower end of the fixing rod 461. The guide plate 463 may be provided in a ring shape. The inner diameter D1 of the guide plate 463 may be equal to or greater than the diameter of the substrate W. The outer diameter D2 of the guide plate 463 may be a length adjacent to the sidewall 410a of the housing 410. When viewed from above, the guide plate 463 may be installed such that its center thereof coincides with the center of the substrate W supported by the support unit 420. The guide plate 463 may be installed to be positioned at the same height as the substrate W when the substrate W is treated.

The fluid discharge unit 470 exhausts the atmosphere of the treatment space 401. Also, the fluid discharge unit 470 discharges the supercritical fluid supplied to the treatment space 401. The fluid discharge unit 470 may include a discharge pipe 472, a pressure reducing member 474, and a discharge valve 476.

One end of the discharge pipe 472 is connected to the discharge port 414b formed in the lower body 414. The other end of the discharge pipe 472 is connected to the pressure reducing member 474. The pressure reducing member 474 may be provided as a motor that provides negative pressure. The supercritical fluid supplied to the treatment space 401 is sequentially discharged to the outside of the housing 410 through the discharge port 414b and the discharge pipe 472. Also, the discharge valve 476 is installed in the discharge pipe 472. The discharge valve 476 may be provided as an opening/closing valve.

The heating unit 480 changes the temperature of the supercritical fluid. According to the exemplary embodiment, the heating unit 480 may be provided as a heater. The heating unit 480 may include a first heater 482 and a second heater 484.

According to the exemplary embodiment, the first heater 482 may be installed on a sidewall of the housing 410. For example, the first heater 482 may be buried inside a sidewall of at least one of the upper body 412 and the lower body 414. The first heater 482 may change the temperature of the supercritical fluid flowing through the treatment space 401 by changing the temperature of the treatment space 401. The first heater 482 may maintain the supercritical fluid supplied to the treatment space 401 in a supercritical fluid phase by heating the supercritical fluid to a temperature equal to or higher than a critical temperature. Furthermore, when the supercritical fluid supplied to the treatment space 401 is liquefied, the first heater 482 may heat the supercritical fluid supplied to the treatment space 401 so as to change the phase to the supercritical phase again.

According to the exemplary embodiment, the second heater 484 may be installed in the fluid supply unit 430. For example, the second heater 484 may be installed in the main supply pipe 432. The second heater 484 may change the internal temperature of the main supply pipe 432 to change the temperature of the supercritical fluid flowing inside the main supply pipe 432. The second heater 484 may heat the supercritical fluid flowing inside the main supply pipe 432 to a temperature equal to or higher than a critical temperature and maintain the supercritical fluid phase. Also, when the supercritical fluid flowing inside the main supply pipe 432 is liquefied, the second heater 484 may increase the internal temperature of the main supply pipe 432 to change the phase to the supercritical phase again.

In the above example, the present invention has been described based on the case where the second heater 484 is installed in the main supply pipe 432 an example, but the present invention is not limited thereto. For example, the second heater 484 may be installed in at least one of the main supply pipe 432, the first supply pipe 442, and the second supply pipe 452.

In the above example, the present invention has been described based on the case where the drying chamber 400 supports the substrate W from the lower side of the housing 410 as an example. However, the present invention is not limited thereto, and the drying chamber 400 may also support the substrate W from the upper side of the housing 410.

Hereinafter, an exemplary embodiment of supporting the substrate W from the upper side of the housing 410 will be described. A description of a configuration overlapping the configuration described with reference to FIGS. 1 to 8 will be omitted and will be described by referring to reference numerals as they are.

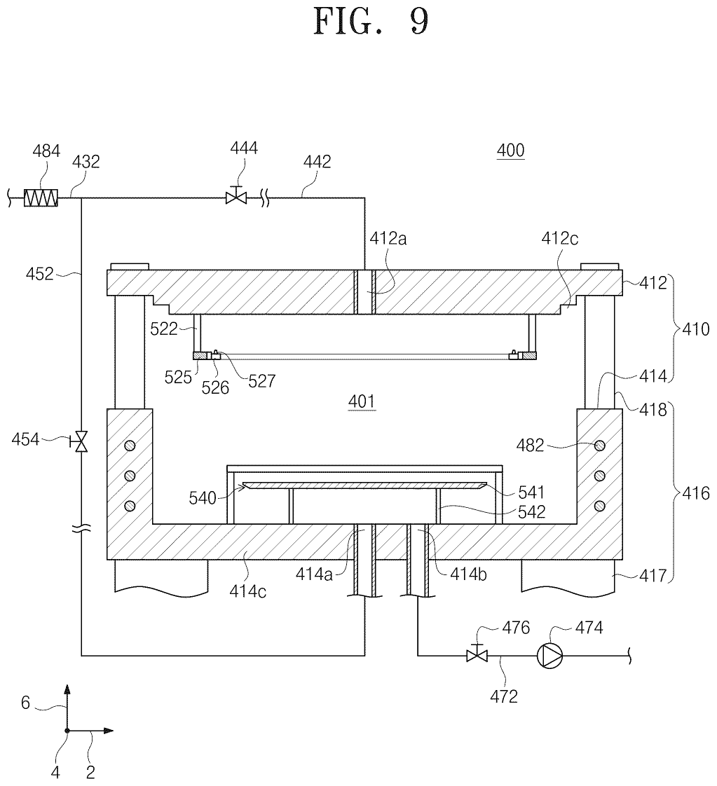

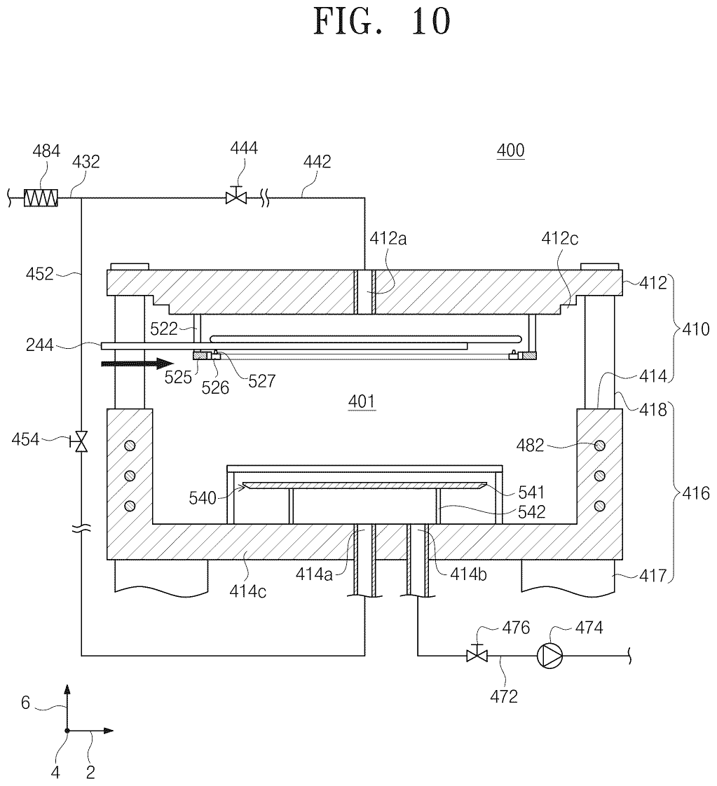

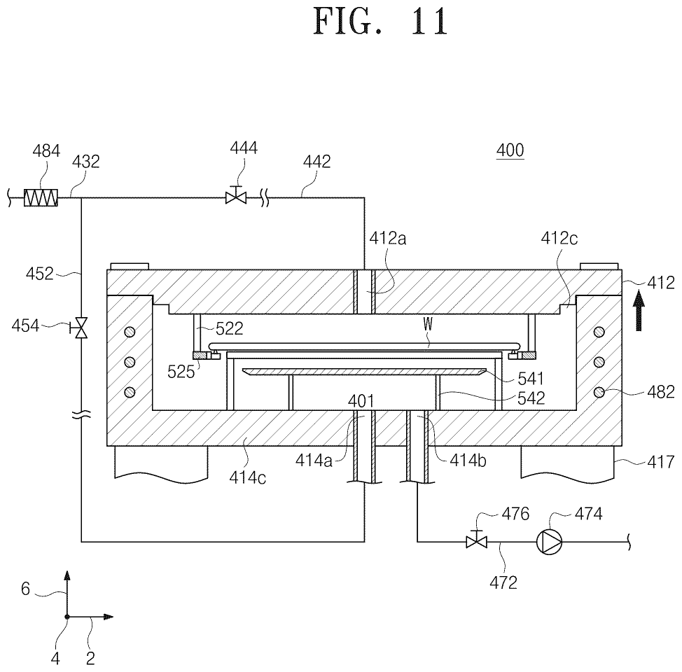

FIG. 9 is a diagram schematically illustrating another exemplary embodiment of the drying chamber of FIG. 4, FIG. 10 is a diagram schematically illustrating a state in which a substrate is loaded into the drying chamber of FIG. 9, and FIG. 11 is a diagram schematically illustrating a state in which a substrate is loaded into and sealed in the drying chamber of FIG. 10.

Referring to FIGS. 9 to 11, the drying chamber 400 includes a support unit 520, a blocking unit 540, and an airflow guide unit 560. The support unit 520 supports the substrate W within the treatment space 401. The support unit 520 may be fixedly installed on the upper wall of the housing 410. The support unit 520 may include a support rod 522, a first support 524, and a second support 525.

The support rod 522 is fixedly installed in the upper body 412. The support rod 522 may be formed to protrude downwardly from the lower surface of the upper body 412. The support rod 522 may have a rod shape. The support rod 522 is provided such that its longitudinal direction faces the vertical direction. A plurality of support rods 522 may be provided. A plurality of support rods 522 are disposed to be spaced apart from each other. When the substrate W is loaded into or unloaded from the space surrounded by the plurality of support rods 522, the plurality of support rods 522 are disposed at positions that do not interfere with the substrate W. The first support 524 and the second support 525 are coupled to the support rods 522.

The first support 524 and the second support 525 are coupled to a lower end of the support rod 522. The first support 524 and the second support 525 are coupled to each other at positions facing each other. The first support 524 and the second support 525 are coupled to be symmetrical to each other.

The first support 524 and the second support 525 may be provided in an arc shape. A support 524 may have an inner diameter greater than a diameter of the substrate W. An extension portion 526 is provided on the first support 524 and the second support 525. The extension portion 526 has a shape protruding from the first support 524 and the second support 525. The extension portion 526 may be extended in a direction toward a space surrounded by the support rods 524. A plurality of extension portions 526 may be provided. The extension portions 526 may be provided on both ends of the first support 524 and the second support 525. According to the exemplary embodiment, the number of extension portions 526 may be four. A support protrusion 527 may be installed on a top surface of the extension portion 526. The support protrusion 527 is provided to support the substrate W. The support 524 may include a first support 524 and a second support 525. The first support 524 and the second support 525 may be disposed to face each other. The shapes of the first support 524 and the second support 525 may be provided to be symmetrical to each other. The first support 524 and the second support 525 may be combined with the first guide plate 564a and the second guide plate 564b to be described later to form a ring shape.

The first support 524 and the second support 525 support a bottom edge region of the substrate W. Due to the above-described structure, the entire upper surface region of the substrate W, a center region of the bottom surface of the substrate W, and a portion of the edge region of the bottom surface of the substrate W may be exposed to the process fluid supplied to the treatment space 401. According to the exemplary embodiment, the bottom surface of the substrate W may be a surface on which a pattern is not formed, and the upper surface of the substrate W may be a surface on which a pattern is formed.

The blocking unit 540 prevents the supercritical fluid supplied from the lower supply port 414a from being directly discharged toward the substrate W and damaging the lower surface of the substrate W. The blocking unit 540 includes a blocking plate 541 and a fixing rod 542.

The blocking plate 541 is disposed in the treatment space 401. The blocking plate 541 may be disposed on the path of the supercritical fluid supplied from the lower supply port 414a. When viewed from above, the blocking plate 541 may be installed at a position overlapping the lower supply port 414a and the discharge port 414b formed in the lower body 414. The blocking plate 541 may be disposed to be spaced apart from the lower wall 414c of the lower body 414 by a predetermined distance upwardly. The fixing rod 542 is coupled to the lower end of the blocking plate 541.

The fixing rod 542 may be provided in a rod shape. A plurality of fixing rods 542 may be provided. A plurality of fixing rods 542 are disposed to be spaced apart from each other by a predetermined distance. The fixing rod 542 is coupled to the lower wall 414c of the lower body 414. The fixing rod 542 is formed to protrude upwardly from the lower wall 414c of the lower body 414. The blocking plate 541 is coupled to the upper portion of the fixing rod 542.

The airflow guide unit 560 may be installed on the lower wall 414c of the housing 410. The airflow guide unit 560 may include a coupling rod 562 and a guide plate 564.

The coupling rod 562 may be provided in a rod shape. The coupling rod 562 is formed to protrude upwardly from the lower wall 414c of the lower body 414. The coupling rod 562 may have a shape extending in the third direction 6 from the lower wall 414c of the lower body 414. A plurality of coupling rods 562 may be provided. A plurality of coupling rods 562 may be provided in the same length.

The guide plate 564 is installed on the coupling rod 562. The guide plate 564 is provided to surround a partial region of the substrate W when the substrate W is treated. The guide plate 564 may include a first guide plate 564a and a second guide plate 564b. The first guide plate 564a and the second guide plate 564b may be provided at a position that does not overlap the blocking plate 541 when viewed from above. The first guide plate 564a and the second guide plate 564b may be installed to be provided at the same height as the substrate W when the substrate W is treated. The first guide plate 564a and the second guide plate 564b may be installed to be provided at the same height as the first support 524 and the second support 525 when the substrate W is treated. The first guide plate 564a and the second guide plate 564b may be provided in an arc shape. The first guide plate 564a and the second guide plate 564b may be disposed to face each other. The first guide plate 564a and the second guide plate 564b may be provided to be symmetrical to each other. The first guide plate 564a and the second guide plate 564b may have the same width as those of the first support 524 and the second support 525. When the substrate W is treated, the first guide plate 564a and the second guide plate 564b may be combined with the first support 524 and the second support 525 to form a ring shape.

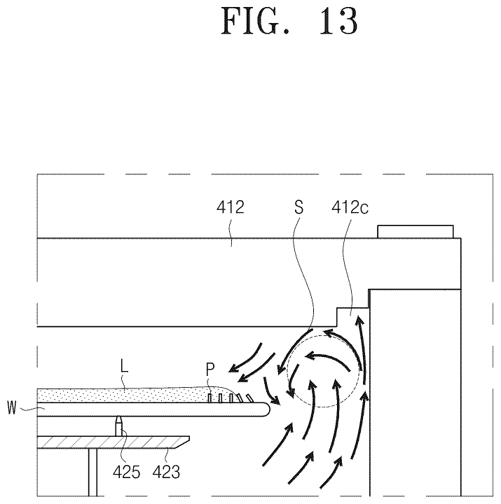

FIG. 13 is a diagram illustrating an appearance of a substrate when a substrate is treated in a general drying chamber. Referring to FIG. 13, when a fluid is supplied to the lower supply port 414a, the fluid is induced by the support plate 423 or the blocking plate 541 to the space between the substrate W and the sidewall 410a of the housing 410. Accordingly, the fluid forms a rising airflow. Also, the fluid that has already risen is directed to the substrate W or descends again. In this case, the substrate W meets the rising fluid to form the vortex S in a region adjacent to the substrate W. The vortex S pushes the liquid film L formed on the substrate. While the liquid film L is pushed, the pattern P formed on the substrate W is pushed out, and the pattern P is damaged.

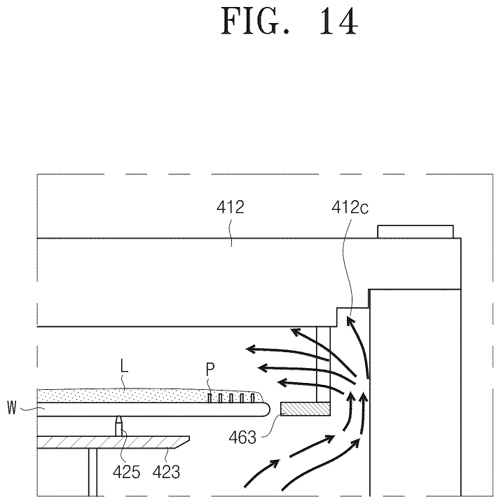

FIG. 14 is a diagram schematically illustrating a state of treating a substrate in the drying chamber according to the exemplary embodiment of the present invention. Referring to FIG. 14, when a fluid is supplied to the lower supply port 414a, the fluid flows to the airflow guide unit 460 by the support plate 423 or the blocking plate 541. The width of the path of the fluid rising by the airflow guide unit 460 is reduced, and the fluid flows to the substrate W along the guide plate 463. Accordingly, vortex formation may be suppressed, and damage to the pattern due to the vortex may be prevented.

In the above example, the guide plate 463 is installed on the fixing rod 461 of which the length is fixed. However, the present invention is not limited thereto, and the cylinder may be provided as a cylinder instead of the fixing rod 461, and the cylinder may be provided to be adjusted in length by a separate driver.

The specification described above provides examples of the present disclosure. Further, the description provides exemplary embodiments of the present disclosure and the present disclosure may be used in other various combinations, changes, and environments. That is, the present disclosure may be changed or modified within the scope of the present disclosure described herein, within a range equivalent to the description, and/or within the knowledge or technology in the related art. The embodiment shows an optimum state for achieving the spirit of the present disclosure and may be changed in various ways for the detailed application fields and use of the present disclosure. Therefore, the detailed description of the present disclosure is not intended to limit the present disclosure in the embodiment. Further, the claims should be construed as including other embodiments.

What is claimed is:

1. An apparatus of processing a substrate, the apparatus comprising:
a housing for providing a treatment space for treating a substrate;
a support unit for supporting a substrate in the treatment space;
a fluid supply unit for supplying a fluid into the treatment space;
a discharge unit for discharging the fluid in the treatment space; and
an airflow guide unit provided in the treatment space,
wherein the airflow guide unit includes a guide plate positioned at an outer side of the substrate in a state where the substrate is supported by the support unit.

2. The apparatus of claim 1, wherein the fluid supply unit includes:
a fluid supply source for storing the fluid; and
a fluid supply line for connecting a lower supply port formed on a lower wall of the housing and the fluid supply source.

3. The apparatus of claim 2, wherein the housing includes:
an upper body;
a lower body positioned on a lower portion of the upper body; and
a lifting member for opening and closing the treatment space by lifting any one of the upper body and the lower body.

4. The apparatus of claim 1, wherein an upper surface of the guide plate is provided to be flat.

5. The apparatus of claim 1, wherein a groove is formed in an edge region of an upper wall of the housing.

6. The apparatus of claim 2, wherein the support unit includes:
a support rod installed on the lower wall of the housing;
a support plate installed on the support rod, spaced apart from the lower wall of the housing, and installed in a path of the fluid supplied to the lower supply port; and
a plurality of support pins installed on the support plate and on which the substrate is placed, and
the airflow guide unit further includes a plurality of fixing rods installed on an upper wall of the housing, and
the guide plate is installed on the fixed rod.

7. The apparatus of claim 6, wherein the guide plate is provided in a ring shape, and
an inner diameter of the guide plate is provided larger than a diameter of the substrate supported by the support unit.

8. The apparatus of claim 7, wherein the guide plate is positioned at the same height as the substrate when the substrate supported on the support plate is treated.

9. The apparatus of claim 2, further comprising:
a blocking plate spaced apart from the lower wall of the housing and installed in a path of the fluid injected from the lower supply port.

10. The apparatus of claim 9, wherein the support unit includes:
a support rod installed on an upper wall of the housing;
a first support and a second support installed on the support rod; and
a plurality of extension portions extending from the first support and the second support and having support protrusions for supporting the substrate, and
the first support and the second support each has an arc shape and is positioned to face each other, and
the airflow guide unit includes:
a first guide plate having an arc shape; and
a second guide plate positioned to face the first guide plate and having an arc shape.

11. The apparatus of claim 10, wherein when the substrate supported by the first support and the second support is treated, the first guide plate and the second guide plate are provided adjacent to the substrate.

12. The apparatus of claim 11, wherein when the substrate supported by the first support and the second support is treated, the first guide plate and the second guide plate are provided to surround a partial region of the substrate supported by the first support and the second support.

13. The apparatus of claim 12, wherein when the substrate is treated, the first support, the second support, the first guide plate, and the second guide plate are arranged to be combined to form a ring when viewed from above.

14. The apparatus of claim 13, wherein when the substrate is treated, the first support, the second support, the first guide plate, and the second guide plate are provided at the same height.

15. An apparatus of processing a substrate, the apparatus comprising:
an upper body;
a lower body for providing a treatment space for treating a substrate in combination with the upper body;
a lifting member for lifting any one of the upper body and the lower body;
a support unit for supporting a substrate in the treatment space;
a fluid supply unit for supplying a supercritical fluid to the treatment space;
a discharge unit for discharging the supercritical fluid in the treatment space;
a blocking plate installed while being spaced apart from a lower wall of the housing; and
an airflow guide unit provided in the treatment space,
the fluid supply unit includes:
a fluid supply source for storing a raw material of the supercritical fluid; and
a fluid supply line for connecting a lower supply port formed on the lower wall of the housing and the fluid supply source,
the support unit includes:
a first support for supporting a first side edge of the substrate; and
a second support for supporting a second side edge of the substrate facing the first side edge,
each of the first support and the second support includes:
a support rod installed on an upper wall of the housing;
a holder installed on the support rod and having an arc shape; and
a support protrusion extending from the holder to an inside thereof,
when viewed from above, the holder is positioned outside the substrate supported by the support unit, and the support protrusion is positioned to overlap an edge region of the substrate supported by the support unit,
the airflow guide unit includes a first guide plate and a second guide plate provided to surround a partial region of the substrate in a state where the substrate is supported by the support unit,
each of the first guide plate and the second guide plate has an arc shape, and
when viewed from above, the substrate supported by the support unit is surrounded by the first guide plate, the holder of the first support, the second guide plate, and the holder of the second support.

16. The apparatus of claim 15, wherein the first guide plate, the holder of the first support, the second guide plate, and the holder of the second support are combined with each other to form a ring in order.

17. The apparatus of claim 16, wherein when the housing is closed, the first guide plate, the holder of the first support, the second guide plate, and the holder of the second support are positioned at the same height.

18. An apparatus of processing a substrate, the apparatus comprising:
an upper body;
a lower body for providing a treatment space for treating a substrate in combination with the upper body;
a lifting member for lifting any one of the upper body and the lower body;
a support unit for supporting a substrate in the treatment space;
a fluid supply unit for supplying a fluid into the treatment space;
a discharge unit for discharging a fluid in the treatment space; and
an airflow guide unit provided in the treatment space,
wherein the fluid supply unit includes:
a fluid supply source for storing the fluid; and
a fluid supply line for connecting a lower supply port formed on a lower wall of the housing and the fluid supply source,
the support unit includes:
a support rod installed in the lower body;
a support plate installed on the support rod; and
a plurality of support pins installed on the support plate and on which the substrate is placed, and
the airflow guide unit includes:
a plurality of fixing rods installed on the upper body; and
a guide plate installed on the fixing rod and surrounding an exterior side of the substrate supported by the support unit in a state where the treatment space is closed.

19. The apparatus of claim 18, wherein when viewed from above, the guide plate is provided in a ring shape.

20. The apparatus of claim 19, wherein the guide plate is adjacent to the substrate supported by the support unit and positioned at the same height as the substrate.
